(19) United States
(12) Patent Application Publication
(10) Pub. No.: US 2026/0282263 A1
(43) Pub. Date: Sep. 17, 2026

(54) SYSTEMS AND METHODS FOR AUTOMATING RACK INVENTORY

(71) Applicant: Dell Products L.P., Round Rock, TX (US)

(72) Inventors: Erik P. SMITH, Douglas, MA (US); Padmanabhan NARAYANAN, Chennai (IN)

(73) Assignee: Dell Products L.P., Round Rock, TX (US)

(21) Appl. No.: 19/077,113

(22) Filed: Mar. 12, 2025

(51) Int. Cl. H05K 7/14; H05K 5/02

(52) U.S. Cl. CPC H05K 7/1492; H05K 5/0252; H05K 5/0286; H05K 7/1498

(57) ABSTRACT

A server rack may may include a plurality of slots, each slot configured to receive a corresponding modular information handling system therein. The server rack may also include a bus bar configured to provide electrical energy to each modular information handling system installed in the plurality of slots, wherein each bus bar comprises a plurality of segments, each segment of the plurality of segments corresponding to a respective slot of the plurality of slots. The server rack may also include a plurality of passive tags, wherein each segment of the plurality of segments includes at least one of the plurality of passive tags, each passive tag of the plurality of passive tags configured to store information regarding a location of such passive tag and transmit the information to an active proximity detector proximate to such passive tag.

### TECHNICAL FIELD

The present disclosure relates in general to information handling systems, and more particularly to systems and methods for mapping power topology in a data center environment.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

In data centers, it may be useful for numerous reasons for an information handling system to be able to report its precise location within a rack to a location service. While various approaches exist for such self-reporting of location, many come with disadvantages. For example, in one existing approach, a series of QR codes may be printed inside of a rack and an information handling system may include a camera to sense the QR code that the information handling system is most proximate to, and thus may report its precise location. However, the disadvantage of such an approach is that it requires a camera and associated processing circuitry to be installed in every information handling system, which imposes substantial cost. Further, such an approach may be non-optimal for non-traditional types of racks.

Accordingly, systems and methods are desired for enabling information handling systems to self-report their locations within a rack without the disadvantages of existing approaches.

### SUMMARY

In accordance with the teachings of the present disclosure, the disadvantages and problems associated with an information self-reporting its location in a rack may be reduced or eliminated.

In accordance with embodiments of the present disclosure, a server rack may may include a plurality of slots, each slot configured to receive a corresponding modular information handling system therein. The server rack may also include a bus bar configured to provide electrical energy to each modular information handling system installed in the plurality of slots, wherein each bus bar comprises a plurality of segments, each segment of the plurality of segments corresponding to a respective slot of the plurality of slots. The server rack may also include a plurality of passive tags, wherein each segment of the plurality of segments includes at least one of the plurality of passive tags, each passive tag of the plurality of passive tags configured to store information regarding a location of such passive tag and transmit the information to an active proximity detector proximate to such passive tag.

In accordance with these and other embodiments of the present disclosure, a modular information handling system may include a bus bar connector configured to electrically couple to a bus bar of a server rack, a slot located proximate to the bus bar connector and configured to receive an active proximity detector, and a management controller communicatively coupled to the slot and configured to, when the bus bar connector is electrically coupled to the server rack, receive location information read by the active proximity detector from a passive tag located on the bus bar connector.

In accordance with these and other embodiments of the present disclosure, a method may include, by an active proximity detector communicatively coupled to a port of a modular information handling system, wherein the port is proximate to a bus bar connector of the modular information handling system, receiving location information read from a passive tag located on a bus bar to which the bus bar connector is electrically coupled and communicating the location information to a management controller of the modular information handling system.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example server rack for receiving modular information handling systems, in accordance with embodiments of the present disclosure;

FIG. 2A illustrates an isometric perspective view of a right side of a bus bar of the server rack shown in FIG. 1, in accordance with embodiments of the present disclosure;

FIG. 2B illustrates an isometric perspective view of a left side of the bus bar shown in FIG. 2A, in accordance with embodiments of the present disclosure;

FIG. 3A illustrates an isometric perspective view of a rear of a modular information handling system and an active proximity detector, in accordance with embodiments of the present disclosure;

FIG. 3B illustrates an isometric perspective view of a rear of the modular information handling system and the active proximity detector with the active proximity detector communicatively coupled to the modular information handling system, in accordance with embodiments of the present disclosure; and

FIG. 4 illustrates an isometric perspective view of the bus bar of FIGS. 2A and 2B electrically coupled to the modular information handling system of FIGS. 3A and 3B, in accordance with embodiments of the present disclosure.

### DETAILED DESCRIPTION

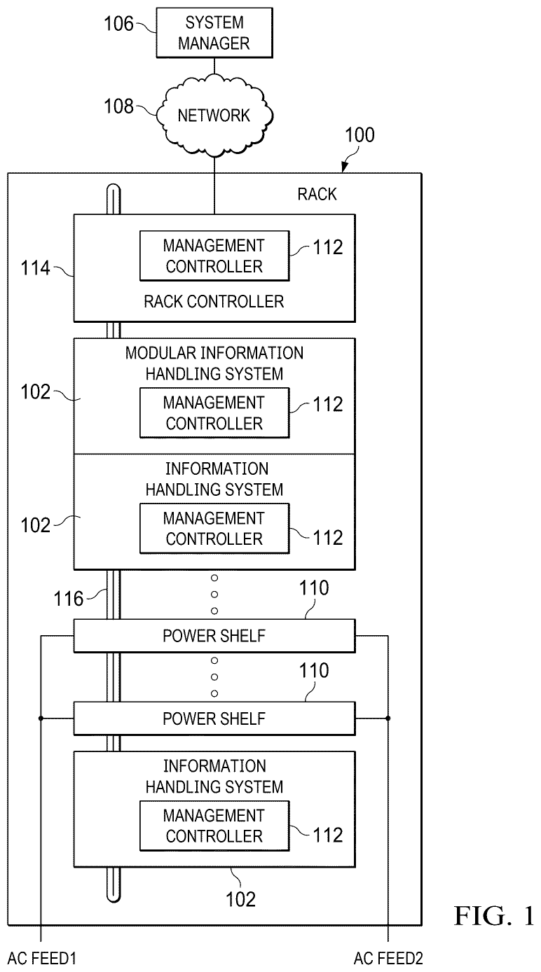

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal data assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, power supplies, air movers (e.g., fans and blowers) and/or any other components and/or elements of an information handling system.

FIG. 1 illustrates a block diagram of an example server rack 100 for receiving modular information handling systems, in accordance with embodiments of the present disclosure. Server rack 100 may be a housing that serves as a container for various information handling systems and information handling resources, and may be constructed from steel, aluminum, plastic, and/or any other suitable material. Although the term “rack” is used, server rack 100 may also be referred to as a case, cabinet, tower, box, enclosure, and/or housing.

Server rack 100 may include a plurality of slots (e.g., bays) each slot configured to receive a modular information handling system 102 therein, with each slot comprising mechanical features that facilitate insertion and removal of a modular information handling system 102, including guiding features to enable electrical coupling of such modular information handling system 102 to a bus bar 116.

As shown in FIG. 1, server rack 100 may be configured to hold and/or provide power, via bus bar 116 and from power supply units present within a plurality of power shelves 110, to a plurality of modular information handling systems 102 and/or information handling resources, and to a rack controller 114 which may also be an information handling system.

As is described in greater detail below, each modular information handling system 102 may include an active proximity detector (e.g., a near-field communication reader) communicatively coupled to a management controller 112 of such modular information handling system 102, wherein such proximity detector may detect proximity to one of a plurality of passive tags (e.g., near-field communication tags) mounted on bus bar 116. Accordingly, with each passive tag storing unique identifying information regarding its location within server rack 100, such active proximity detector may determine a location of such modular information handling system 102 within server rack 100, and communicate information regarding such location to management controller 112 of such modular information handling system 102.

A management controller 112 may comprise any system, device, or apparatus configured to facilitate management and/or control of information handling system 102 and/or one or more of its component information handling resources. A management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. A management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

Once a management controller 112 has received location information from its associated modular information handling system active proximity detector, it may communicate such information to management controller 112 of rack controller 114. In turn, management controller 112 of rack controller 114 may communicate the location information to a system manager 106 (e.g., a management console) via network 108.

To enable communication between management controllers 112 of modular information handling systems 102 and management controller 112 of rack controller 114, an internal communication network may exist within server rack 100. For example, in some embodiments, such communication network may be implemented using power line communication (PLC) via bus bar 116.

Network 108 may be a network and/or fabric configured to couple system manager 106 to information handling systems 102 and/or one or more other information handling systems. In these and other embodiments, network 108 may include a communication infrastructure, which provides physical connections, and a management layer, which organizes the physical connections and information handling systems communicatively coupled to network 108. Network 108 may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, the Internet or any other appropriate architecture or system that facilitates the communication of signals, data and/or messages (generally referred to as data). Network 108 may transmit data via wireless transmissions and/or wire-line transmissions using any storage and/or communication protocol, including without limitation, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or any other transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 108 and its various components may be implemented using hardware, software, or any combination thereof.

In addition to those components explicitly shown in FIG. 1, server rack 100 may include one or more other components. Also, in addition to those components explicitly shown in FIG. 1, modular information handling systems 102 and rack controller 114 may include any other information handling resources.

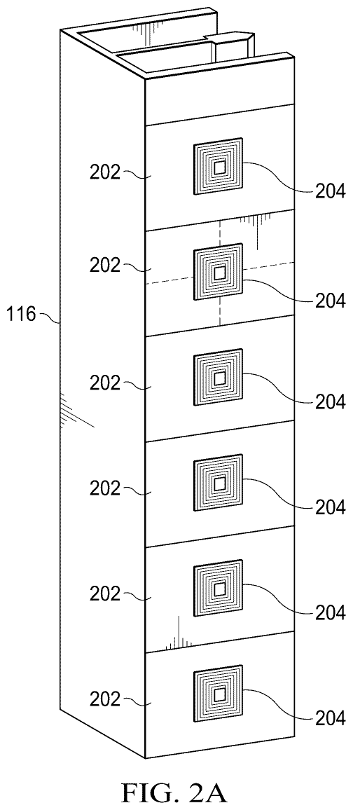

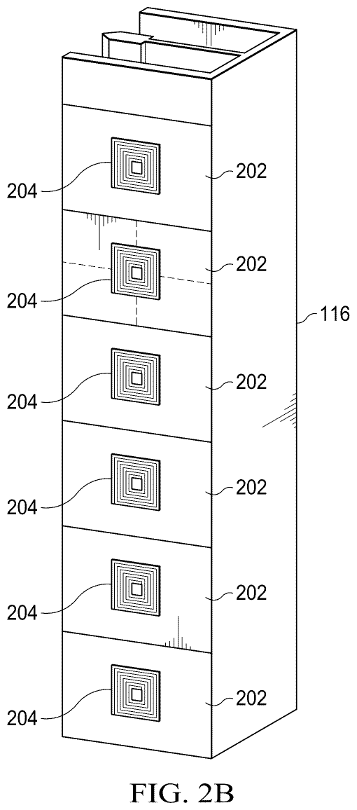

FIG. 2A illustrates an isometric perspective view of a portion of a right side of bus bar 116, in accordance with embodiments of the present disclosure. FIG. 2B illustrates an isometric perspective view of a portion of a left side of bus bar 116, in accordance with embodiments of the present disclosure. As shown in FIGS. 2A and 2B, bus bar 116 may include a plurality of segments 202, each segment 202 corresponding to a respective location at which bus bar 116 may receive and electrically couple to a modular information handling system 102. As also shown in FIGS. 2A and 2B, a plurality of passive tags 204 (e.g., near-field communication tags) may be mounted on either or both of the left side and right side of bus bar 116, with each passive tag 204 located vertically at an approximate midpoint of height of a modular information handling system 102 when inserted into bus bar 116 proximate to such passive tag 204. Each passive tag 204 may include information regarding its location, including without limitation its rack unit number within server rack 100, a serial number for bus bar 116, a rack number for server rack 100, a pod number in which server rack 100 is located, identifying information of a data center in which server rack 100 is located, etc.

In some embodiments, it may be desirable to include passive tags on both the left side and right side of bus bar 116, as bus bar 116 may be installed with a right or left bias within server rack 100 and not necessarily in the center.

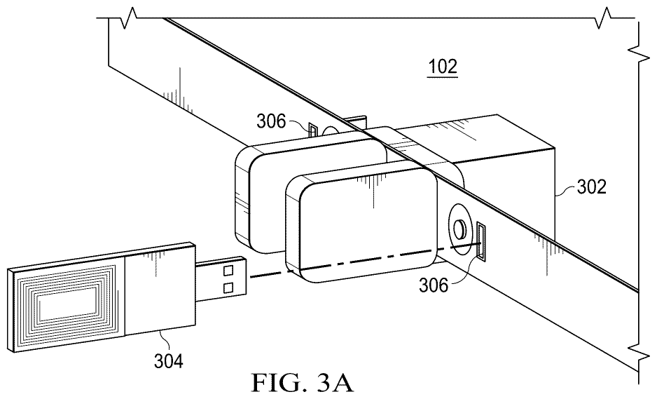

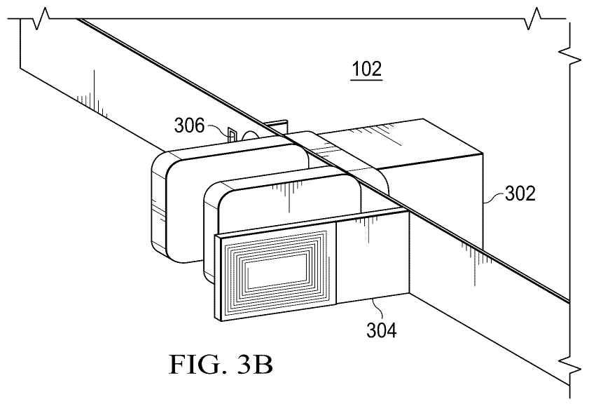

FIG. 3A illustrates an isometric perspective view of a rear of a modular information handling system 102 and an active proximity detector 304, in accordance with embodiments of the present disclosure. FIG. 3B illustrates an isometric perspective view of a rear of such modular information handling system 102 and active proximity detector 304 with active proximity detector 304 communicatively coupled to such modular information handling system 102, in accordance with embodiments of the present disclosure.

Active proximity detector 304 may comprise any system, device, or apparatus configured to read passive tags 204. For example, active proximity detector 304 may include a controller (e.g., NFC controller), a reader antenna (e.g., an NFC reader antenna), and a connector (e.g., a Universal Serial Bus Type-A connector).

As also shown in FIGS. 3A and 3B, modular information handling system 102 may include a bus bar connector 302 for electrically coupling modular information handling system 102 to bus bar 116, and one or more ports 306 (e.g., Universal Serial Bus Type-A ports) located in close proximity to bus bar connector 302 for receiving a corresponding active proximity detector 304.

In some embodiments, active proximity detector 304 may be coupled to either the right side or left side port 306 of modular information handling system 102 depending on whether bus bar 116 has a left or right bias. If bus bar 116 is installed within server rack 100 without a bias, then active proximity detector 304 may be installed in either port 306 without loss of generality.

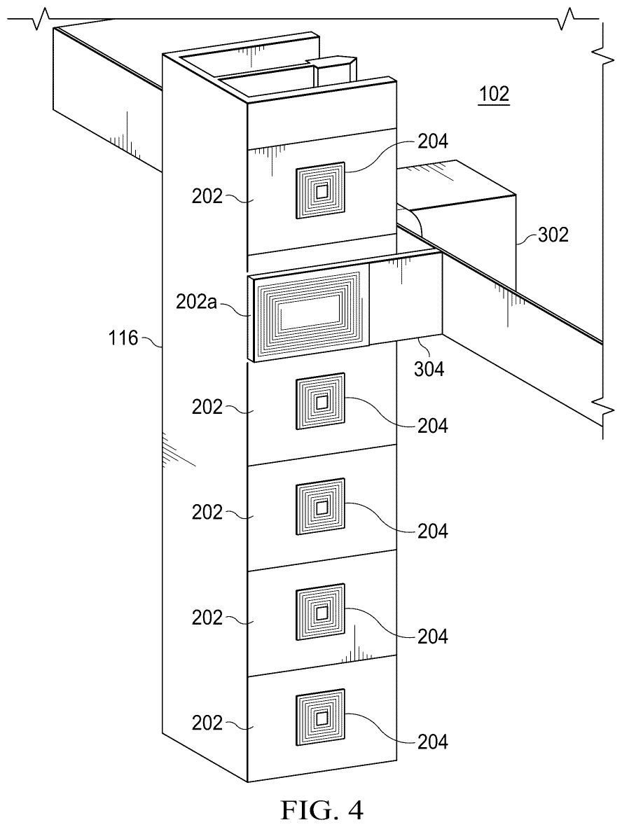

FIG. 4 illustrates an isometric perspective view of a modular information handling system 102 electrically coupled (e.g., via its bus bar connector 302) to bus bar 116, in accordance with the present disclosure. As shown in FIG. 4, after such electrical coupling, active proximity detector 304 may be sufficiently proximate to a passive tag 204 located within segment 202A on bus bar 116, thus enabling active proximity detector 304 to read location data from such passive tag 204, and communicate such location information to management controller 112 of modular information handling system 102, which may further communicate such location information to rack controller 114. In addition, rack controller 114 may forward such location information to system manager 106 via network 108.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A server rack comprising:
a plurality of slots, each slot configured to receive a corresponding modular information handling system therein;
a bus bar configured to provide electrical energy to each modular information handling system installed in the plurality of slots, wherein each bus bar comprises a plurality of segments, each segment of the plurality of segments corresponding to a respective slot of the plurality of slots; and
a plurality of passive tags, wherein each segment of the plurality of segments includes at least one of the plurality of passive tags, each passive tag of the plurality of passive tags configured to:
store information regarding a location of such passive tag; and
transmit the information to an active proximity detector proximate to such passive tag.

2. The server rack of claim 1, wherein each of the passive tags comprises a near-field communication tag.

3. The server rack of claim 1, wherein each segment of the plurality of segments includes two passive tags on opposite sides of the bus bar from each other.

4. A modular information handling system comprising:
a bus bar connector configured to electrically couple to a bus bar of a server rack;
a slot located proximate to the bus bar connector and configured to receive an active proximity detector; and
a management controller communicatively coupled to the slot and configured to, when the bus bar connector is electrically coupled to the server rack, receive location information read by the active proximity detector from a passive tag located on the bus bar connector.

5. The modular information handling system of claim 4, wherein the management controller is further configured to, in response to receiving the location information, communicate the location information to another information handling system.

6. The modular information handling system of claim 4, wherein the active proximity detector comprises a near-field communication reader.

7. A method comprising, by an active proximity detector communicatively coupled to a port of a modular information handling system, wherein the port is proximate to a bus bar connector of the modular information handling system:
receiving location information read from a passive tag located on a bus bar to which the bus bar connector is electrically coupled; and
communicating the location information to a management controller of the modular information handling system.

8. The method of claim 7, wherein the active proximity detector comprises a near-field communication reader.

9. The method of claim 7, wherein the passive tag comprises a near-field communication tag.
